(19) United States
(12) Patent Application Publication
(10) Pub. No.: US 2013/0057302 A1
(43) Pub. Date: Mar. 7, 2013

(54) CAPACITIVE MEASURING CIRCUIT INSENSITIVE TO HIGH-FREQUENCY INTERFERENCE

(71) Applicant: Marian Jozef Walter Slezak, Rijsbergen (NL)

(72) Inventor: Marian Jozef Walter Slezak, Rijsbergen (NL)

(73) Assignee: FLUID WELL INSTRUMENTS B.V., Baarle-Nassau (NL)

(21) Appl. No.: 13/560,027

(22) Filed: Jul. 27, 2012

(30) Foreign Application Priority Data
Jul. 28, 2011 (NL) 2007186

(51) Int. Cl. G01R 27/26

(52) U.S. Cl. 324/681

(57) ABSTRACT

The invention relates to a measuring circuit for measuring the capacitance of a measuring capacitor which has a first and a second measuring electrode and which is coupled to a charging capacitor, wherein the frequency of the output signal of the measuring circuit is a measure of the capacitance of the capacitor, and the measuring circuit comprises a buffer amplifier with which the point between the charging resistor and the measuring capacitor is connected to the other components of the measuring circuit. The buffer amplifier changes the high impedance level of the combination of the measuring capacitor and the charging resistor to a level at which low-pass filters can usefully be applied. Buffer amplifiers are also available with an input capacitance and input resistance such that the buffer amplifier already functions in itself as a low-pass filter. An external filter is then not necessary because the filter is already present in the buffer amplifier.

Capacitive measuring circuits for measuring the content of a vessel are generally known. In such measuring circuits the two measuring electrodes are placed in the vessel and the capacitance between the two measuring electrodes, which do after all together form a capacitor, is measured. Assuming that the measuring electrodes are placed fixedly in the vessel, the capacitance of this capacitor depends on the dielectric constant of the materials in the volume in which the electrical field between the measuring electrodes extends. Many substances have a dielectric constant differing from the dielectric constant of air, so that the capacitance of the capacitor is a good measure of the extent of filling of the vessel. When two substances are present in the vessel, the volume ratio of these two substances can be measured by means of measuring the capacitance. More options are created when more than two measuring electrodes are applied and in the case of use in channels.

When these measurements are applied within electrically conductive vessels, these measurements are fairly insensitive to high-frequency interference from outside. More and more use is being made in recent times of vessels manufactured from non-electrically conductive material, whereby high-frequency interference signals in particular can occur, making performing of the measurements much more difficult. Apart from such measurement situations, it also occurs that the cables necessary for connecting the diverse components cannot be shielded, or hardly so, so that irrespective of the measurement configuration the cables themselves pick up interference and function as source of interference.

Because mainly high-frequency signals are involved and the measurements generally have a low-frequency progression, it is in principle attractive to use frequency filters to separate the high-frequency interference signals from the measurement signal.

Thus known from GB-A-2 279 756 is a measuring circuit for measuring the capacitance of a measuring capacitor which is provided with a first and a second measuring electrode and which is coupled to a charging capacitor, wherein the frequency of the output signal of the measuring circuit is a measure of the capacitance of the capacitor, and wherein the measuring circuit comprises a buffer amplifier in which the junction between the charging resistor and the measuring capacitor is connected to the other components of the measuring circuit. This is a measuring circuit for measuring the permittivity of coins.

The measurement takes place however at high to very high impedances. What are involved here are measuring signals which vary only slowly and capacitors with very small capacitances. The use of filters therefore results immediately in interference in the measurements. It is of course possible to apply low-pass filters, but the capacitors necessary for such a filter for the purpose of a useful dimensioning have capacitances which are many times greater than those of the actual measuring capacitor, so that the presence of a filter and the associated high capacitance makes variations in the—small-capacitance of the measuring capacitor hardly detectable in the resulting output signal, let alone that they can serve as basis for measurements. The object of the invention is to provide such a measuring circuit which is considerably less sensitive to high-frequency interference.

This object is achieved with such a circuit, wherein the buffer amplifier is provided with a low-pass filter. This low-pass filter can be embodied as a separate low-pass filter, although the low-pass filter can likewise be integrated into the buffer amplifier.

An effect of the buffer amplifier is the change in the high impedance level of the combination of the measuring capacitor and the charging resistor to a level at which low-pass filters can usefully be applied. Buffer amplifiers are also available with an input capacitance and input resistance such that the buffer amplifier already functions in itself as a low-pass filter. In this embodiment a separate filter is not necessary because the filter is already present in the buffer amplifier.

According to the first preferred embodiment, the buffer amplifier comprises an operational amplifier provided with feedback. Operational amplifiers are amplifiers which are usually available as integrated circuit and which, in addition to having a high amplification factor, have high input impedances so that they usually have excellent properties for the application anticipated here, wherein the feedback brings about the desired change in the impedance level.

In order to enable a wholly free choice of the properties of the low-pass filter, for instance to enable tuning thereof to the interference occurring in a determined situation, it is recommended that the buffer amplifier is connected by means of a low-pass filter to the other parts of the measuring circuit. The values of the components of the low-pass filter can then be selected in order to optimize the filter, since they are no longer dependent on the intrinsic properties of the amplifier. It will be apparent that the designer of the filter makes use of the impedances already present in the amplifier when dimensioning the filter.

Although other configurations are not precluded, it is recommended that the low-pass filter comprises an RC element. A simple filter configuration is thus created with properties sufficient for this application.

Use is preferably made of a measuring circuit provided with an oscillator, wherein the measuring capacitor and the charging resistor form the components defining the frequency of the oscillator. Such measuring circuits do after all have a simple structure.

In order to enable easy filtering out of the high-frequency interference signals it is attractive for the resistance value of the resistor of the RC filter element to be at least an order of magnitude smaller than the resistance value of the charging resistor.

According to a corresponding variant, the RC time constant of the RC filter element is at least an order of magnitude smaller than the RC time constant of the components defining the frequency of the oscillator.

As alternative to the above elucidated measuring circuits provided with an RC oscillator, the present embodiment provides a measuring circuit provided with a triangular voltage generator, the output connection of which is coupled to the first measuring electrode, and with a comparator circuit, the input connection of which is connected to the second measuring electrode, wherein the buffer amplifier is connected between the second measuring electrode and the comparator circuit. Such circuits likewise have a simple structure and can be attractive in some situations.

The insensitivity to interference signals is further increased when the buffer amplifier is provided with a feedback circuit embodied as a filter. This will after all filter out high-frequency interference signals appearing at the measuring electrode.

The second measuring electrode is preferably connected by means of a low-pass filter to the input connection of the buffer amplifier.

It is also attractive in this configuration for the buffer amplifier to comprise a low-pass filter.

In order to be as effective as possible, the RC time constant of the at least one low-pass filter is at least an order of magnitude smaller than the RC time constant of the components defining the frequency of the oscillator.

The invention also relates to a measuring device comprising a measuring circuit according to any of the foregoing claims, wherein the measuring device is adapted to measure a property of a fluid present in a vessel or a channel, and the first and the second measuring electrode are placed such that the electric field between the first and the second measuring electrode extends over the content of the vessel or the channel.

The invention further relates to a method for measuring the capacitance of a measuring capacitor provided with a first and a second measuring electrode, wherein the frequency of the output signal of the measuring circuit is a measure of the capacitance of the capacitor, wherein the signal from the measuring capacitor is fed by means of a buffer amplifier to the other components of the measuring circuit.

The present invention will be elucidated hereinbelow with reference to the accompanying drawings, in which:

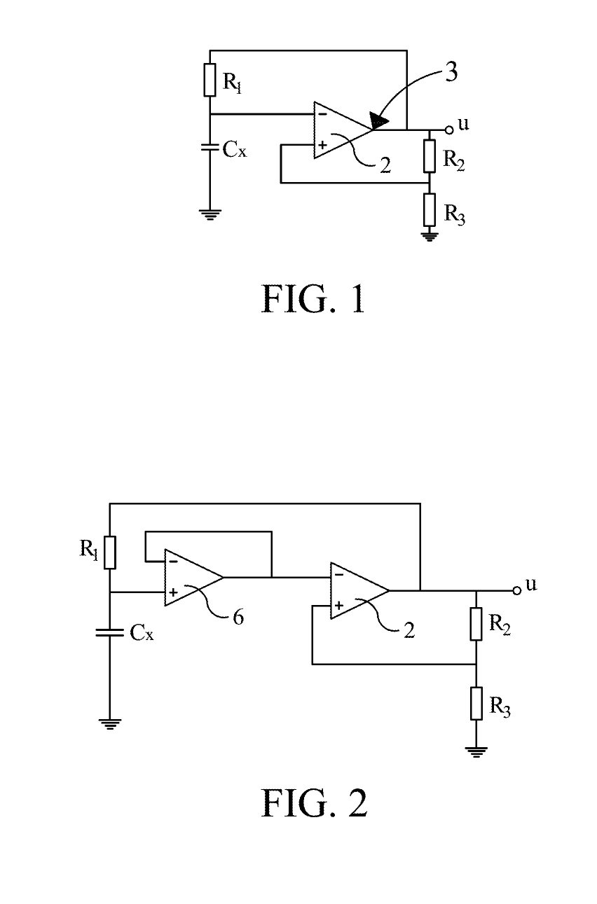

FIG. 1 shows a diagram of a prior art capacitive measuring circuit;

FIG. 2 shows a diagram of a first embodiment of a measuring circuit according to the invention;

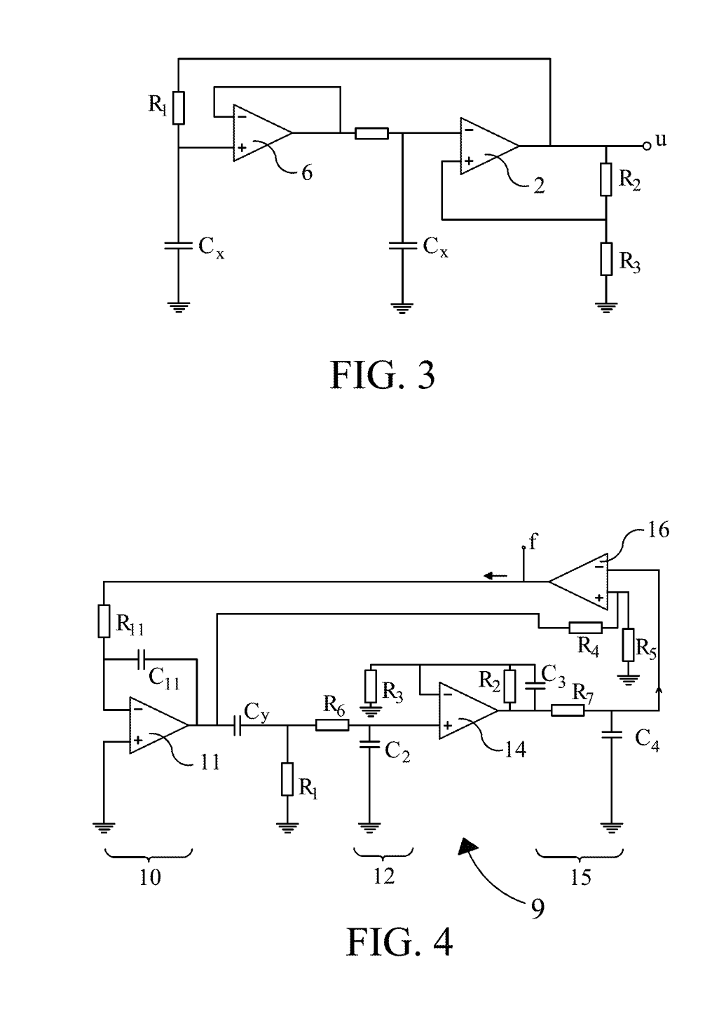

FIG. 3 shows a diagram of a second embodiment; and

FIG. 4 shows a diagram of a third embodiment.

FIG. 1 shows a prior art capacitive measuring circuit 1. The measuring circuit comprises an operational amplifier 2 which operates as comparator and the output connection 3 of which is connected to the output connection 4 of measuring circuit 1. Output connection 3 is connected via two resistors R² and R₃ to earth. These resistors R₂ and R₃ together form a voltage divider and the connecting point of these two resistors R₂ and R₃ is connected to the non-inverting input connection of the operational amplifier 2 operating as comparator. Output connection 3 is also connected via a charging resistor R₁ to the first electrode of the measuring capacitor C_{X}. This capacitor C_{X} forms of the capacitor of which the capacitance is measured for the purpose of measuring the degree of filling of a vessel or other quantity on which the capacitance of capacitor C_{X} depends. The second electrode of measuring capacitor C_{X} is connected to earth. The first electrode of measuring capacitor C_{X} is also connected to the inverting input connection of the operational amplifier 2 functioning as comparator.

Charging resistor R₁ and measuring capacitor C_{X} together form an RC circuit with a resonance frequency. Now that this is incorporated in the feedback loop of the operational amplifier, the whole circuit forms an oscillator, the frequency of which is defined by the formula:

F=1/R₁·C_{X}.

It is noted that the value of C_{X} is small, usually in the order of magnitude of between 0.1 pF and 10 pF. It follows herefrom that, for a properly measurable frequency in the order of magnitude of 100 kHz, the charging resistor R₁ must have a value of about 100 kΣ to 100 MΣ.

According to a first embodiment of the invention, the diagram of which is shown in FIG. 2, an operational amplifier 6 is added in order to cope with high-frequency interference. This operational amplifier 6 functions as buffer amplifier. The output connection of the operational amplifier is connected to the inverting input connection of the operational amplifier 2 of measuring circuit 1 functioning as comparator. The inverting input connection of operational amplifier 6 is connected to the output connection thereof so that a negative feedback is created. The non-inverting input connection of operational amplifier 6 is connected to the connecting point between measuring capacitor C_{X} and charging resistor R₁. The main function of operational amplifier 6, being amplification, does not contribute per se toward suppressing high-frequency interference, although the amplification does cause a change in the impedance level, whereby a filter can be added more easily. The inherent impedances of operational amplifier 6, which are in fact parasitic, do however usually form a filter here which in many cases already produces good results in terms of suppressing interference signals.

The circuit shown in FIG. 3, which represents a second embodiment of the invention, differs from the embodiment shown in FIG. 2 only in the presence of a filter 7 which is formed by a series resistor R₄ and a capacitor C₁ leading to earth. Filter 7 here supplements the inherent input impedances of operational amplifier 6. It is possible with a suitable choice of the values of the components to modify the turnover frequency of the filter for the purpose of optimizing the interference-absorbing function of the filter.

Finally, FIG. 4 shows an embodiment of the invention wherein another type of oscillator is applied. This is a circuit adapted to charge the measuring capacitor with a sawtooth voltage. Created as a result at another electrode of the measuring capacitor is a block-like signal which is fed to a comparator.

The circuit more particularly comprises a sawtooth generator 10 provided with an operational amplifier 11, a capacitor C₁₁ and a resistor R₁₁. The non-inverting input connection of operational amplifier 11 is connected here to earth and the inverting input connection thereof is connected by a parallel circuit of resistor R₁₁ and capacitor C₁₁ to the output connection of operational amplifier 11. A sawtooth voltage is thus created on the output connection of operational amplifier 11.

The output connection of operational amplifier 11 is connected to a first electrode of measuring capacitor C_{X}, the second electrode of which is connected to a resistor R₁ leading to earth and functioning as current-voltage converter. The discharge current of measuring capacitor C_{X} is hereby converted to a voltage which can be utilized more easily by the subsequent parts of the circuit.

The connecting point between resistor R₁ and measuring capacitor C_{X} is also connected to a first low-pass filter 12 comprising a resistor R₆ and a capacitor C₂.

The output connection of the first low-pass filter 12 is connected to the non-inverting input connection of an operational amplifier 14 functioning as buffer amplifier. The inverting input connection of operational amplifier 14 is connected to a feedback circuit which functions as second low-pass filter and which is provided with a parallel circuit of a resistor R₂ and a capacitor C₃. The inverting input connection of the operational amplifier is likewise connected to earth via a resistor R₃.

The output connection of operational amplifier 14 is connected to a third low-pass filter 15 formed by a resistor R₇ and a capacitor C₄ leading to earth. The output connection of the third low-pass filter 15 is connected to the inverting input connection of an operational amplifier 16 which functions as comparator and the non-inverting input connection of which is connected via a resistor R₅ to earth and connected via a resistor R₄ to the output connection of the sawtooth generator. The output signal, the frequency of which is a measure of the capacitance of capacitor C_{X}, comes available at the output connection of the operational amplifier 16 functioning as comparator. The output signal of operational amplifier 16 is also fed as trigger signal to sawtooth generator 10.

It is noted in the case of this circuit that the operational amplifier 16 functioning as comparator is, as is usual, not provided with feedback. It will be apparent that at a small value of C_{X} the charging and discharging takes place more quickly than at a greater value of C_{X}, so that the frequency of the signals circulating in the circuit is a measure of the capacitance of capacitor C_{X}.

It will be apparent that the combination of a low-pass filter and an amplifier with which the surprising effect of the invention is obtained can also be applied with oscillators of other configuration.

What is claimed is:

1. A measuring circuit for measuring the capacitance of a measuring capacitor comprising a first and a second measuring electrode and being coupled to a charging capacitor, wherein the frequency of the output signal of the measuring circuit is a measure of the capacitance of the capacitor, the measuring circuit comprising:
a buffer amplifier in which the junction between the charging resistor and the measuring capacitor is connected to the other components of the measuring circuit, wherein the buffer amplifier is provided with a low-pass filter.

2. The measuring circuit as claimed in claim 1, wherein the low-pass filter comprises an RC element.

3. The measuring circuit as claimed in claim 2, wherein the resistance value of the resistor of the RC filter element is at least an order of magnitude smaller than the resistance value of the charging resistor.

4. The measuring circuit as claimed in claim 1, wherein the buffer amplifier comprises an operational amplifier provided with feedback.

5. The measuring circuit as claimed in claim 4, wherein the operational amplifier is connected so as to function as a low-pass filter.

6. The measuring circuit as claimed in claim 1, wherein the second measuring electrode is connected by a low-pass filter to the input connection of the buffer amplifier.

7. The measuring circuit as claimed in claim 1, wherein the measuring circuit comprises an oscillator, and that the measuring capacitor and the charging resistor form the components defining the frequency of the oscillator.

8. The measuring circuit as claimed in claim 7, wherein the oscillator is provided with an operational amplifier.

9. The measuring circuit as claimed in claim 7, wherein the RC time constant of the RC filter element is at least an order of magnitude smaller than the RC time constant of the components defining the frequency of the oscillator.

10. The measuring circuit as claimed in claim 1, wherein the measuring circuit is provided with a triangular voltage generator, the output connection of which is coupled to the first measuring electrode, and with a comparator circuit, the input connection of which is connected to the second measuring electrode, wherein the buffer amplifier is connected between the second measuring electrode and the comparator circuit.

11. The measuring circuit as claimed in claim 10, wherein the output connection of the buffer amplifier is connected by a low-pass filter to the input connection of the comparator circuit.

12. The measuring circuit as claimed in claim 11, wherein the RC time constant of the at least one low-pass filter is at least an order of magnitude smaller than the RC time constant of the components defining the frequency of the oscillator.

13. A measuring device comprising a measuring circuit as claimed in claim 1, wherein the measuring device is adapted to measure a property of a fluid present in a vessel or a channel, and that the first and the second measuring electrode are placed such that the electric field between the first and the second measuring electrode extends over the content of the vessel or the channel.

14. A method for measuring the capacitance of a measuring capacitor provided with a first and a second measuring electrode, wherein the frequency of the output signal of a measuring circuit is a measure of the capacitance of the capacitor, the method comprising:
feeding the signal from the measuring capacitor by means of a buffer amplifier to the other components of the measuring circuit.
